(19) United States
(12) Patent Application Publication
(10) Pub. No.: US 2012/0167963 A1
(43) Pub. Date: Jul. 5, 2012

(54) Photovoltaic Device Structure with Primer Layer

(76) Inventor: Stanford R. Ovshinsky, Bloomfield Hills, MI (US)

(21) Appl. No.: 12/983,149

(22) Filed: Dec. 31, 2010

(51) Int. Cl. H01L 31/0376; H01L 31/0264; C01B 33/02; H01L 31/02

(52) U.S. Cl. 136/255; 136/252; 136/258; 136/261; 423/348

(57) ABSTRACT

Device structure that facilitates high rate plasma deposition of thin film photovoltaic materials at microwave frequencies. The device structure includes a primer layer that shields the substrate and underlying layers of the device structure during deposition of layers requiring aggressive, highly reactive deposition conditions. The primer layer prevents or inhibits etching or other modification of the substrate or underlying layers by highly reactive deposition conditions. The primer layer also reduces contamination of subsequent layers of the device structure by preventing or inhibiting release of elements from the substrate or underlying layers into the deposition environment. The presence of the primer layer extends the range of deposition conditions available for forming photovoltaic or semiconducting materials without compromising performance. The invention allows for the ultrafast formation of silicon-containing amorphous semiconductors from fluorinated precursors in a microwave plasma process. The product materials exhibit high carrier mobility, high photovoltaic conversion efficiency, low porosity, little or no Staebler-Wronski degradation, and low concentrations of electronic and chemical defects.

### FIELD OF INVENTION

This invention relates to thin film photovoltaic devices. More particularly, this invention relates to a device structure that includes a primer layer that enables high speed deposition of the active material of a photovoltaic device. Most particularly, this invention relates to a device structure that permits plasma deposition of a high purity photovoltaic material at microwave frequencies from a highly reactive deposition medium. The product of the invention has an ultra-low concentration of chemical contaminants and electronic defects, and provides a photovoltaic material with unprecedented conversion efficiency that achieves cost parity with fossil fuels.

### BACKGROUND OF THE INVENTION

Concern over the depletion and environmental impact of fossil fuels has stimulated strong interest in the development of alternative energy sources. Significant investments in areas such as batteries, fuel cells, hydrogen production and storage, biomass, wind power, algae, and solar energy have been made as society seeks to develop new ways of creating and storing energy in an economically-competitive and environmentally-benign fashion. The ultimate objectives are to minimize society's reliance on fossil fuels and to avoid the production of greenhouse gases.

A number of experts have concluded that to avoid the serious consequences of global warming, it is necessary to maintain CO₂ at levels of 350 ppm or less. To meet this target, based on current projections of world energy usage, the world will need 17 TW of carbon-free energy by the year 2050 and 33 TW by the year 2100. The estimated contribution of various carbon-free sources toward the year 2050 goal are summarized below:

| | Projected Energy |
|---|---|
| Source | Supply (TW) |
| Wind | 2-4 |
| Tidal | 2 |
| Hydro | 1.6 |
| Biofuels | 5-7 |
| Geothermal | 2-4 |
| Solar | 600 |

Based on the expected supply of energy from the available carbon-free sources, solar energy is clearly the most viable solution for reducing greenhouse emissions and alleviating the effects of global climate change. (See J. Esch, “Keeping the Energy Debate Clean How Do We Supply the World's Energy Needs?”, IEEE Proc. 98(1), 39-41 (2010).)

Amorphous semiconductors are attractive materials for solar energy applications. Among the amorphous semiconductors, amorphous silicon is known to be a particularly promising solar energy material. Unlike crystalline silicon, amorphous silicon is a direct gap material that has strong absorption over much of the solar spectrum. The strong absorption means that high efficiency solar cells can be formed from thin layers of amorphous silicon. As a result, solar panels based on amorphous silicon (or chemically- or structurally-modified forms of amorphous silicon, including composite forms of amorphous silicon that include nanocrystalline, microcrystalline, or polycrystalline phases) are lightweight, flexible, and readily adapted to field use in a variety of installation environments.

S. R. Ovshinsky has long recognized the advantages of amorphous silicon and related materials as the active layer of solar cells and has been instrumental, through his inventions and discoveries, in advancing automated and continuous manufacturing techniques for producing solar and photovoltaic devices based on amorphous semiconductors or combinations of amorphous semiconductors with nanocrystalline, microcrystalline, polycrystalline or single crystalline semiconductors. Representative achievements of S. R. Ovshinsky in the field of amorphous semiconductors and photovoltaic materials include U.S. Pat. Nos. 4,400,409 (describing a continuous manufacturing process for making thin film photovoltaic films and devices); 4,410,588 (describing an apparatus for the continuous manufacturing of thin film photovoltaic solar cells); 4,438,723 (describing an apparatus having multiple deposition chambers for the continuous manufacturing of multilayer photovoltaic devices); 4,217,374 (describing suitability of amorphous silicon and related materials as the active material in several semiconducting devices); 4,226,898 (demonstration of solar cells having multiple layers, including n- and p-doped); 5,103,284 (deposition of nanocrystalline silicon and demonstration of advantages thereof); and 5,324,553 (microwave deposition of thin film photovoltaic materials).

Current efforts in thin film photovoltaic material manufacturing are directed at increasing the deposition rate without impairing photovoltaic efficiency and, in the case of silicon-containing materials, without exacerbating Staebler-Wronski degradation. Higher deposition rates lower the cost of thin film solar cells and can lead to a dramatic decrease in the unit cost of electricity obtained from solar energy. As the deposition rate increases, thin film photovoltaic materials become increasingly competitive with fossil fuels as a source of energy. Presently, PECVD (plasma-enhanced chemical vapor deposition) is the most cost-effective method for the commercial-scale manufacturing of amorphous silicon and related amorphous semiconductor photovoltaic materials. Current PECVD processes provide uniform coverage of large-area substrates with device quality photovoltaic material at deposition rates of ˜1-5 Å/s. This deposition rate, however, is insufficient to achieve cost parity with fossil fuels.

In order to enhance the economic competitiveness of plasma deposition processes, it is desirable to increase the deposition rate. To effectively compete with fossil fuels, it is believed that deposition rates of 100 Å/s or higher are needed. The deposition rate of prevailing plasma deposition techniques is limited by the high concentration of intrinsic defects that develops in the product photovoltaic film as the deposition rate is increased. The intrinsic defects include structural and electronic defects such as dangling bonds, strained bonds, unpassivated surface states, non-tetrahedral bonding distortions, and coordinatively unsaturated atoms (e.g. two- or three-fold coordinated silicon or germanium). The intrinsic defects create electronic states in the bandgap of amorphous semiconductors. The electronic states detract from solar conversion efficiency by (1) promoting nonradiative recombination processes that deplete the concentration of free carriers generated by absorbed sunlight and (2) reducing the mobility of free carriers (especially minority carriers (holes)). Intrinsic defects also contribute to degradation of the solar conversion efficiency of amorphous silicon and related materials through the Staebler-Wronski effect, an effect that leads to a 15-30% reduction in photovoltaic efficiency with use over time.

To minimize the concentration of intrinsic defects, current plasma deposition processes are performed at low deposition rates. By slowing the deposition process, the intrinsic defects that form in the as-deposited product material have the opportunity to equilibrate to energetically-favored states that have more regular bonding configurations. As a result, the concentration of intrinsic defects is reduced. Unfortunately, the reduced deposition rate impairs the economic competitiveness of the process and prevents cost parity with fossil fuels.

A number of strategies have been proposed for increasing the deposition rate of photovoltaic materials prepared from plasma processes. S. R. Ovshinsky, for example, has demonstrated that the concentration of intrinsic defects formed in plasma-deposited materials depend on the distribution of species present in the plasma. A plasma is a complex state of matter that includes ions, ion-radicals, neutral radicals and molecules in multiple energetic states. S. R. Ovshinsky has shown that certain charged species can be detrimental to the quality of as-deposited amorphous semiconductors under typical plasma deposition conditions because they promote the creation of defects. Uncontrolled charged species tend to strike the deposition surface with high kinetic energy and can damage a developing thin film material through bond cleavage and the ejection of material from the surface. Bond cleavage creates dangling bonds and promotes the formation of locally strained coordination environments that contribute to electronic defect states. Ejection of material from the surface can alter the composition of a developing thin film material because of differences in the rate of release of different elements. The product film, for example, may become enriched in elements with a high binding energy to the developing thin film material and depleted in elements with a low binding energy. In contrast, S. R. Ovshinsky has shown that neutral plasma species frequently promote more uniform bonding and lead to lower defect concentrations in as-deposited material.

In U.S. patent application Ser. Nos. 12/199,656; 12/209,699; and 12/429,637; S. R. Ovshinsky described techniques for minimizing the deleterious effect of uncontrolled charged plasma species on the defect concentration. The patent applications describe techniques for maximizing the presence of beneficial neutral species and controlling the presence and activity of deleterious charged species at the deposition surface. The techniques include preferential formation of neutral species in the plasma activation process, regulation of charged species magnetic confinement, and sequestration of undesirable charged species to form a charge-controlled deposition medium. Through utilization of a charge-controlled deposition medium, the optimal balance of charged and neutral species in a plasma can be realized. As a result, high quality photovoltaic and semiconducting materials, including amorphous silicon, can be formed at high deposition rates in a plasma deposition process while minimizing the presence of defects.

A second strategy for increasing the deposition rate of plasma-based processes is to increase the plasma frequency. Conventional plasma deposition processes are typically completed at radiofrequencies (e.g. 13.56 MHz). As the plasma frequency is increased, the source gases used in plasma deposition are activated more efficiently, more completely, and to higher energy states. Plasma excitation at microwave frequencies (e.g. 2.45 GHz), for example, leads to higher dissociation rates of source gases, generates higher fluxes of ions and neutrals, and creates a higher proportion of plasma species (ions, neutrals) sufficiently energetic to participate in the deposition process. The high dissociation rates and higher excitation energies associated with microwave plasmas improve process efficiency by providing higher utilization of source gases than radiofrequency plasmas. The high fluxes and energies of ions and neutrals produced by microwave plasmas lead to significantly higher thin film deposition rates than radiofrequency plasmas.

In addition to dissociation of a higher fraction of source gases, the high deposition rate accompanying microwave deposition of thin film precursors is also a consequence of the enhanced reactivity of deposition intermediates. Enhanced reactivity of deposition intermediates results from the higher energy of activation available from microwave excitation. Microwave excitation produces deposition intermediates with higher internal energy by activating deposition precursors to higher energy electronic and vibrational excited states. The higher internal energy makes the deposition intermediates less stable and more conducive to the structural rearrangements and reactions on the deposition surface needed to form a thin film material.

Although enhanced reactivity of deposition precursors is beneficial from the standpoint of deposition rate, it oftentimes leads to unintended side effects. A common problem in microwave deposition is the tendency of reactive deposition intermediates to form thin films away from the substrate. Thin film coatings, for example, may develop on the interior walls of the deposition chamber and may serve as a source of contamination for subsequent depositions.

Since the deposition chamber is normally operated under vacuum or with a controlled atmosphere, it has a limited volume and receives precursors, background gases, and energy from external sources. Materials are generally delivered by conduits through valves that pierce the boundaries of the chamber. Electrical energy (such as the bias between electrodes needed to initiate a plasma or the resistive dissipation used to heat a substrate) is typically supplied by wires that connect an external power source through the boundaries of the chamber to internal components. The formation of thin film coatings on the openings or actuators of internal valves, or on internal components such as electrodes or wires, may alter deposition conditions, impair the uniformity of deposition or prevent deposition altogether.

Unintended thin film coatings are particularly problematic when they form on the windows of a deposition chamber through which the electromagnetic energy used to activate a plasma from deposition precursors is transmitted. In microwave deposition, the microwave generator is normally located remote from the deposition chamber. The generator produces microwaves and transmits them along a microwave waveguide to the deposition chamber or a downstream applicator, where the microwaves pass through a window to energize deposition intermediates or activate deposition precursors to generate the reactive species used to form a thin film material. To maximize the microwave energy coupled to the deposition intermediates or precursors, it is necessary to insure that the window is highly transparent to microwave frequencies. If the reactive species generated by the microwaves deposit the thin film material on the window and the thin film material absorbs microwaves, the transparency of the window decreases.

Decreased transparency of the window leads to two detrimental effects. First, any decrease in transparency leads to a reduction in the microwave energy coupled to the deposition intermediates or precursors. Reduced microwave coupling means that the deposition species are less dissociated, less energetic, less reactive, and as a result, the deposition rate decreases. Second, continued exposure of a microwave-absorptive thin film on the window to microwave radiation leads to localized heating of the thin film material that can cause thermal stresses and potentially catastrophic failure of the window.

Many desirable photovoltaic materials, including amorphous silicon and silicon-germanium, absorb microwave radiation and are difficult to manufacture in a microwave plasma process because the high reactivity conditions present in a microwave plasma promotes the formation of undesirable coatings on the windows used to transmit microwave radiation to the deposition environment. The formation of window coatings is particularly problematic when hydrogenated silicon precursors (e.g. silane or disilane) are used for the microwave deposition of photovoltaic or semiconducting materials. Microwave activation of hydrogenated silicon precursors is thought to enhance the rate of formation of polysilane byproducts that have a tendency to coalesce or aggregate from the plasma phase to form thin film coatings on the microwave windows of the deposition chamber.

In U.S. patent application Ser. No. 12/855,626, S. R. Ovshinsky et al. described a microwave deposition apparatus for the formation of amorphous silicon and other silicon-containing photovoltaic and semiconducting materials that avoided the formation of microwave-absorbing coatings on the microwave transmission windows. The apparatus including a microwave applicator that housed spatially-separated conduits for delivering two or more deposition precursors. Microwaves launched in the applicator are transmitted through the boundaries of the conduits to excite the deposition precursors.

The design objective of the apparatus was to provide simultaneous microwave excitation of isolated deposition precursors to prevent interactions between deposition precursors in the plasma-activated state that facilitate formation of thin film byproducts on the conduit boundaries. The plasma-activated deposition precursors were transported away from the microwave excitation region, directed toward a substrate, and recombined for formation of a thin film product. S. R. Ovshinsky et al. recognized the benefit of hydrogen in reducing the Staebler-Wronski effect in amorphous silicon and the need to prevent interactions between hydrogen and silicon in the microwave excitation region of the apparatus to avoid formation of polysilane coatings on the precursor delivery conduits. Accordingly, to implement the apparatus, hydrogen-containing precursors and silicon-containing precursors were activated in separate conduits and a non-hydrogenated silicon precursor was utilized. SiF₄, for example, was identified as a suitable non-hydrogenated silicon precursor and was shown not to form microwave-absorbing thin film byproducts on the conduit boundaries. S. R. Ovshinsky et al. showed that high efficiency amorphous silicon materials could be prepared at high deposition rates in a microwave deposition process by activating SiF₄ and one or more hydrogen-containing precursors (e.g. H₂, SiH₄, Si₂H₆) in separate conduits and recombining the activated deposition species at a substrate positioned away from the region of microwave excitation.

Although successful depositions were made and the use of a fluorinated silane precursor proved beneficial, the presence of fluorine in the deposition environment may lead to unintended side effects. Fluorine, for example, is known to be highly reactive and may function as an etchant. When fabricating multi-layer structures, the introduction of fluorinated precursors for the deposition of a particular target layer may lead to etching of the deposition surface upon which the target layer is formed. The deposition surface might be a substrate or an underlying layer of the intended device structure. One consequence of etching is the removal of elements from the deposition surface and transfer of etched elements to the deposition environment of the target layer. The presence of etched elements from the deposition surface may be undesirable because such elements may interfere with the deposition of the target layer. Etched elements represent a potential source of contamination and may alter the kinetics or mechanism of the deposition of the layer. These effects may inhibit the deposition rate of the target layer, introduce defects in the target layer, and/or alter the structure or composition of the target layer. There is a need for a plasma process that permits the use of non-hydrogenated precursors in the deposition of photovoltaic and semiconducting materials.

### SUMMARY OF THE INVENTION

The amount of energy absorbed by the Earth's atmosphere, oceans and land masses in one hour is more than the amount of energy used by people on Earth in one year. This fact reveals that solar energy is the ultimate solution to eliminating mankind's dependence on fossil fuels. Implementation of solar energy on a scale sufficient to meaningfully reduce fossil fuel consumption has been hindered, however, by economics. This invention addresses concerns about cost by providing a process and device structure that enables high speed deposition of thin film photovoltaic materials that exhibit high conversion efficiencies.

With the invention, the unit cost of solar energy will be decreased to or below the cost of fossil fuels. As a result, widespread implementation of the instant invention will allow mankind to reduce its dependence on fossil fuels and serves the higher goal of democratizing energy by enabling all countries, regardless of natural resources, to become self-sufficient in energy. Concerns over the scarcity of fossil fuels, conflicts over sources of fossil fuel will be eliminated, and national and worldwide security will be enhanced.

The invention is predicated on a fundamental advance in plasma chemistry and physics that allows for a tremendous increase in the throughput and deposition rate of photovoltaic materials in a continuous manufacturing process. The fundamental advance in plasma chemistry and physics enables a unique atomic engineering of multi-element compositions that affords a method of controlling and forming thin film photovoltaic materials in the presence of a microwave plasma. With the invention, the deposition rate of thin film photovoltaic materials based on silicon can be dramatically increased for the first time without introducing the defects, the density of states and Staebler-Wronski degradation that have heretofore diminished photovoltaic efficiency and frustrated efforts to achieve cost parity with fossil fuels.

With the invention, it is possible to direct the evolution of a photovoltaic material in situ in a plasma process to achieve several effects that combine to provide a new form of matter in an exceedingly short deposition time. The plasma deposition environment includes a reactive species capable of etching the active photovoltaic material as it forms. The activity of the reactive species is controlled to maintain a constructive balance between the rates of etching and deposition. The invention demonstrates that a controlled level of etching is beneficial because it removes defects and perfects the structure of the active photovoltaic material in real time.

As an active photovoltaic material forms, atoms are often incorporated in less-than-optimal configurations and it has been heretofore required to slow the deposition process to enable equilibration of the structure to reduce the concentration of defects. With the instant invention, defects are removed and the structure of the depositing material is repaired on the fly without a need to delay the deposition process. Through proper management of the activity of the etchant and proper design of the device structure, the restorative benefit associated with etching can be realized and the detrimental effects related to overetching and contamination can be avoided.

The invention enables for the first time a gigawatt or more of manufacturing capacity in a single machine of a size that fits within an ordinary manufacturing plant. Because of this invention, it will no longer be necessary to run multiple manufacturing processes in multiple locations in parallel or to build multiple machines in series to realize output on the gigawatt scale. The tremendous cost reduction afforded by this invention will motivate the development of new industries that will provide high-valued jobs that stimulate the economy and promote the educational system.

The foregoing benefits of the instant invention are more particularly realized in the exemplary embodiments now summarized:

The invention provides a multilevel device structure that includes a substrate, an active layer and a primer layer disposed between the substrate and the active layer. The device structure may be used in the fields of photovoltaics, semiconductors, and electronics. Representative substrates include metals and insulators, including steel, aluminum, quartz, plastics, and glass. The device structure can be fabricated in a batch or continuous process using discrete or continuous web substrates.

In one embodiment, the active layer comprises silicon and has photovoltaic or semiconducting properties. The structure of the active layer may include an amorphous phase, a nanocrystalline phase, a microcrystalline phase, a polycrystalline phase, or a combination of two or more of such phases. The active layer may include alloys of silicon with germanium or other elements to achieve bandgap tuning as well as chemical modifiers such as hydrogen and fluorine to control structure and improve performance.

The primer layer is an integral part of the device structure and serves as an intermediary during fabrication of the device that shields the substrate and intervening layers from the deposition environment used to form the active layer. The presence of the primer layer permits deposition of the active layer with precursors or under conditions that might otherwise damage or modify the substrate. In one embodiment, the active layer is formed by a plasma-enhanced chemical vapor deposition (PECVD) process and the deposition environment includes one or more precursors (or fragments thereof) that would etch or otherwise chemically modify the substrate in the absence of the primer layer. The primer layer also protects the substrate from physical damage caused by high energy collisions of ions or electrons produced in the plasma deposition environment used to form the active layer.

In addition to protecting the substrate from harsh deposition environments, the primer layer serves the dual purpose of protecting the active material from contamination with elements that may be released from the substrate through chemical or physical processes at the deposition conditions used to form the active material. In one embodiment, the primer layer is stable and impervious to the deposition conditions used to form the active material. In another embodiment, the primer layer is composed of elements that are compatible with the active material. Elements compatible with the active material are elements that do not materially affect the characteristics of the active material if released from the primer layer and incorporated into the active material. In a further embodiment, the primer layer is composed of elements that may be released at the deposition conditions used to form the active layer, but which do not become incorporated in the active layer.

In one embodiment, the active material includes silicon-containing photovoltaic or semiconducting material and the primer layer includes a non-oxide material. The non-oxide material may be a metal, semiconductor or dielectric. Representative primer layers include silicon, silicon nitride, germanium, and germanium nitride. In another embodiment, the active material includes a fluorine-containing photovoltaic or semiconducting material formed from a plasma deposition process and the primer layer is a material formed from a plasma deposition process that lacks fluorine or a material that includes fluorine formed from a non-plasma deposition process.

In one embodiment, the primer layer is in direct contact with the substrate. In other embodiments, one or more intervening layers are positioned between the substrate and the primer layer and the primer layer is in direct contact with one of the intervening layers. The intervening layers may include one or more of an adhesion layer, a conductive layer (e.g. grid line, electrical contact, transparent conductive oxide), and other active materials (e.g. a n-type or p-type semiconducting material). In one embodiment, the device structure includes a substrate, an n-type or p-type semiconducting layer, a primer layer, and an intrinsic semiconducting layer, where the primer layer is disposed between the n-type or p-type layer and the intrinsic layer. In one embodiment, the active material is in direct contact with the primer layer.

Device structures that incorporate a primer layer in accordance with the invention include photovoltaic devices and semiconducting devices. Photovoltaic devices include single cell, tandem cell, and triple cell configurations. The photovoltaic devices may include a p-i-n junction. Semiconducting devices include n-type or p-type devices and p-n junctions. In one embodiment, the primer layer includes a semiconducting material. In one embodiment, the primer layer is p-type or n-type and the active material is intrinsic. In another embodiment, the primer layer is p-type and the active material is intrinsic or n-type. In one embodiment, the primer layer is n-type and the active material is intrinsic or p-type.

Inclusion of the primer layer in the instant device structures expands the range of conditions at which active photovoltaic and semiconducting materials can be formed without concerns over contamination of the active material with elements from the substrate or underlying intervening layers. The primer layer permits the use of more aggressive (chemical or physical) conditions in the deposition of the active material. The instant inventors have demonstrated that aggressive deposition conditions can improve the performance of many photovoltaic and semiconducting materials by enabling greater control over structure and bonding and greatly reducing the concentration of defects. Inclusion of fluorine, for example, in the deposition environment of silicon-containing photovoltaic or semiconducting materials greatly improves performance and enables deposition at heretofore unprecedented rates. With the instant invention, high deposition rates of thin film photovoltaic and semiconducting materials based on silicon can be realized without introducing the contaminants, defects, density of states, and Staebler-Wronski degradation that have diminished the efficiency and deposition rate of prior art materials. The purity, performance and deposition rate available from the instant invention represents a new paradigm in solar technology that provides cost parity with fossil fuels.

### BRIEF DESCRIPTION OF THE DRAWING

FIG. 1 depicts a device structure with a substrate, a primer layer, and an active layer.

FIG. 2 depicts a device structure with a substrate, one or more intervening layers, a primer layer, and an active layer.

FIG. 3 depicts a system for the microwave deposition of thin film materials.

FIG. 4 depicts in side view an embodiment of a microwave applicator with conduits delivering different deposition species.

FIG. 5 depicts a system for the microwave deposition of thin film materials that includes at least one energized deposition medium stream and at least one non-energized deposition medium stream.

FIG. 6 shows the dependence of μτ product of the active layer on primer layer thickness for a series of devices.

FIG. 7 shows the wavelength dependence of quantum efficiency for a photovoltaic device that includes a primer layer and an active layer along with comparable data for reference samples of amorphous silicon and microcrystalline silicon.

FIG. 8 shows the Raman spectrum of a photovoltaic device that includes a primer layer and an active layer.

FIG. 9 shows the wavelength dependence of quantum efficiency for photovoltaic device samples that include a common active layer and either no primer layer or one of two primer layers.

FIG. 10 depicts a portion of a deposition system that includes a moving continuous web substrate.

### DETAILED DESCRIPTION OF THE ILLUSTRATED EMBODIMENTS

Although this invention will be described in terms of certain preferred embodiments, other embodiments that are apparent to those of ordinary skill in the art, including embodiments that do not provide all of the benefits and features set forth herein and including embodiments that provide positive benefits for high-volume manufacturing, are also within the scope of this invention. Accordingly, the scope of the invention is defined only by reference to the appended claims.

This invention concerns materials and device structures that facilitate the high-speed deposition of photovoltaic products that exhibit high conversion efficiency, high free carrier mobility, low concentrations of chemical and electronic defects, and little or no Staebler-Wronski degradation. The invention emphasizes photovoltaic products based on amorphous silicon and enables formation of high quality amorphous silicon from a highly reactive deposition environment while avoiding overetching and contamination of the layers of the device structure. The highly reactive deposition environment improves the structure and bonding of amorphous silicon and passivates or inhibits defects to enable deposition of amorphous silicon at high rates in a microwave plasma process.

Amorphous silicon (and alloys or modified forms thereof) is a promising thin film photovoltaic material that has the potential to displace fossil fuels as the primary source of energy for society. In order to realize the potential of amorphous silicon, it is necessary to reduce the cost of producing amorphous silicon and maximize its photovoltaic efficiency. The strategy for reducing the cost of amorphous silicon that is expected to have the greatest impact is to increase deposition rate. As noted hereinabove, the fastest deposition rates are provided by plasma-based deposition techniques. PECVD, in particular, is currently the leading commercial method for producing thin film amorphous silicon and provides deposition rates on the order of a few Angstroms per second.

The leading commercial process for the PECVD deposition of amorphous silicon employs plasma excitation of a silicon-containing precursor gas. The deposition rate of the leading commercial plasma deposition techniques is limited by the high concentration of intrinsic defects that develops in amorphous silicon and related materials as the deposition rate is increased. The intrinsic defects include structural defects such as dangling bonds, strained bonds, unpassivated surface states, non-tetrahedral bonding distortions, and coordinatively unsaturated atoms (e.g. two- or three-fold coordinated silicon or germanium). The structural defects create electronic states in the bandgap and near the band edges that reduce solar conversion efficiency. To minimize the concentration of intrinsic defects, the leading commercial plasma deposition processes are performed at low deposition rates. By slowing the deposition process, the intrinsic defects that form in a thin film as it deposits have an opportunity to relax or equilibrate to energetically-favored states that have more regular bonding configurations. As a result, the concentration of intrinsic defects is reduced.

To improve the economic competitiveness of plasma-based deposition techniques, it is desirable to develop a process that provides high deposition rates without creating a high concentration of defects. One approach for increasing deposition rate is to increase the plasma frequency. To minimize the formation of intrinsic defects, the leading commercial PECVD processes utilize radiofrequency plasma excitation (e.g. 13.56 MHz). Higher deposition rates, however, are in principle possible at microwave frequencies. Relative to radiofrequency excitation, plasma excitation at microwave frequencies (e.g. 2.45 GHz) leads to higher dissociation rates of source gases, generates higher fluxes of ions and neutrals, creates a higher proportion of plasma species (ions, neutrals) sufficiently energetic to participate in the deposition process, and increases the reactivity of deposition intermediates by increasing internal energy. The high fluxes and energies of ions and neutrals produced by microwave plasmas lead to significantly higher thin film deposition rates than radiofrequency plasmas.

Because of its availability and commensurately reasonable cost, silane (SiH₄) has been the most widely used deposition precursor for amorphous silicon. Silane, however, is known to produce material that has poor electronic properties due to the presence of a high concentration of dangling and strained bonds. Plasma deposition of amorphous silicon from silane in the presence of high hydrogen (H₂) dilution, however, has been shown to improve the electronic properties of amorphous silicon. Inclusion of excess hydrogen in the deposition process has the effect of passivating dangling bonds and relieving bond strain to provide a material with a lower concentration of defects, a lower density of states, and better carrier transport properties.

One of the drawbacks associated with utilizing high hydrogen dilution in forming amorphous silicon is a degradation of photovoltaic efficiency over time upon exposure to solar radiation due to the Staebler-Wronski effect. Although high hydrogen dilution conditions form amorphous silicon materials with improved photovoltaic efficiency, much of the improvement is only temporary because of the Staebler-Wronski effect. The origin of the Staebler-Wronski effect is not fully understood, but is believed to involve a photogeneration of electronic defect states or carrier trapping centers by incident solar radiation. The extent of the degradation has been observed to become more severe as the extent of hydrogen dilution increases.

A pronounced Staebler-Wronski effect is one reason why attempts in the prior art to prepare amorphous silicon in a microwave plasma deposition process have been unsuccessful. Although microwave plasma frequencies have been shown to provide high deposition rates in the prior art, the resulting amorphous silicon material has suffered from an unacceptably high degree of Staebler-Wronski degradation. It is believed that the more energetic conditions associated with microwave plasmas relative to radiofrequency plasmas releases too much hydrogen from the silane (SiH₄) precursor. As a result, an especially high degree of hydrogen dilution develops in the deposition environment when silane is activated by a microwave plasma and the amorphous silicon product exhibits an especially pronounced Staebler-Wronski effect.

Efforts to increase the plasma deposition rate of amorphous silicon from silane by increasing the plasma frequency to the microwave regime have also been frustrated by the presence of solid phase (particulate) silanaceous byproducts and dihydride defects. It has been observed that the production of silanaceous byproducts and dihydride defects increases with increasing plasma frequency in PECVD processes. The silanaceous byproducts are thought to be long chain or polymeric compounds of silicon and hydrogen (e.g. polysilanes) and deposit throughout the deposition chamber, including on the windows used to couple microwave energy to silane and/or hydrogen. Since the silanaceous byproducts absorb microwave radiation, microwave deposition of silane under conditions of hydrogen dilution has proven to be commercially impractical because surfaces coated with silanaceous byproduct can be heated to unsafe temperatures when exposed to the source microwave radiation used in the deposition process. Incorporation of silanaceous byproducts in amorphous silicon is also thought to contribute to Staebler-Wronski degradation. Dihydride defects are sites of bonding irregularity that arise in amorphous silicon when the concentration of SiH₂ radicals in the deposition environment is high. Dihydride defects produce electronic states in the bandgap of amorphous silicon that act as efficient traps that limit carrier mobility and promote internal recombination of photogenerated carriers.

To minimize Staebler-Wronski degradation and dihydride defects in the product material and to avoid overproduction of silanaceous byproducts, commercial processes that exploit the benefits of available from hydrogen dilution are limited to radiofrequency plasma deposition processes. The less energetic radiofrequency plasma excitation avoids excess production of hydrogen radicals from silane (or hydrogen) and limits the formation of silanecous byproducts and dihydride defects. Because of the need to limit the plasma frequency to the radiofrequency range, the deposition rates of amorphous silicon prepared from silane under conditions of high hydrogen dilution have been low.

To realize the enhanced deposition rates available from microwave plasmas while avoiding the drawbacks of high hydrogen dilution, S. R. Ovshinsky has proposed incorporating fluorine into amorphous silicon. S. R. Ovshinsky has shown that fluorinated deposition species are advantageous because fluorine promotes regular tetrahedral coordination of column IV elements (silicon, germanium and tin) in thin film materials, relieves bond strain, acts to passivate dangling bonds and other defects that produce tail states or midgap states that compromise carrier mobility in photovoltaic materials, and assists in the formation of nanocrystalline, intermediate range order, or microcrystalline phases of silicon and germanium.

The presence of fluorine in microwave plasma deposition is believed to facilitate new structural organizations of silicon and other elements present in the deposition environment, at the deposition surface, or in the bulk of the depositing or underlying layers. The new structural organizations are a form of atomic engineering that enables the high speed formation of silicon-containing photovoltaic materials in a bonding configuration that avoids defects and improves photovoltaic efficiency. The instant inventors believe that inclusion of fluorine in the composition of silicon-containing amorphous semiconductors can also remedy the Staebler-Wronski effect by strengthening bonds and improving the structural integrity of the material to render it less susceptible to light-induced defect creation.

Many of the benefits of fluorine in amorphous silicon materials are due to the particularly high strength of the Si—F bond. The high bond strength favors association of silicon at the deposition surface with fluorine in the deposition environment and inhibits thermal dissociation of fluorine from silicon during the deposition process. These effects act to reduce the concentration of dangling bonds within the bulk and on the surface of amorphous silicon. The high bond strength of fluorine with silicon also tends to impose a more consistent and more nearly regular tetrahedral bonding configuration on silicon. Preferential formation of the regular bonding configuration has the effect of eliminating bond strain and bond distortions that can lead to the creation of defect states.

For representative illustrations of the benefits of fluorine in amorphous photovoltaic and semiconducting materials see the following references by S. R. Ovshinsky: U.S. Pat. No. 5,103,284 (formation of nanocrystalline silicon from SiH₄ and SiF₄); U.S. Pat. No. 4,605,941 (showing substantial reduction in defect states in amorphous silicon prepared in presence of fluorine); and U.S. Pat. No. 4,839,312 (presents several fluorine-based precursors for the deposition of amorphous and nanocrystalline silicon); the disclosures of which are incorporated by reference herein.

As noted hereinabove, the use of silane as a deposition precursor in microwave plasma deposition may result in conditions of high hydrogen dilution that lead to more severe Staebler-Wronski degradation. While recognizing that a controlled degree of hydrogen dilution is beneficial and wishing to realize the benefits of fluorine in a high rate microwave deposition process, S. R. Ovshinsky and colleagues have developed a microwave deposition method and apparatus designed to form amorphous silicon from a fluorinated silicon precursor. (See U.S. patent application Ser. No. 12/855,626; the disclosure of which is hereby incorporated by reference herein.)

In one illustrative embodiment, an amorphous silicon photovoltaic material with a low density of states and high photovoltaic efficiency can be formed at high deposition rates by using SiF₄ as a deposition precursor in a microwave plasma deposition process. SiF₄ can be supplied to a microwave applicator for excitation via a dedicated delivery conduit that excludes hydrogen gas (H₂) or other hydrogenated precursors. Hydrogen or other hydrogenated precursor gases can be supplied in a separate delivery conduit to the applicator for microwave excitation. Spatial separation of the source of silicon from the source of hydrogen prevents interactions between silicon and hydrogen in the microwave activation region and permits deposition of higher quality amorphous, intermediate range order, nanocrystalline, and microcrystalline forms of silicon in a high-rate microwave plasma process.

Since SiF₄ is free from hydrogen, its excitation or activation by microwave radiation does not lead to the production of polysilane or related byproducts. Similarly, microwave activation or excitation of hydrogen in the absence of silicon occurs without the production of undesirable solid phase byproducts and without the production of SiH₂ radicals. As a result, the formation of unintended hydrogenated silanaceous coatings on the microwave window is avoided, the severity of Staebler-Wronski degradation is significantly reduced (or even eliminated), and the formation of dihydride defects is prevented. With the deposition apparatus, the distribution of species needed to form high quality silicon-based photovoltaic materials can be created in a continuous process at high deposition rates without concerns over corrupting the microwave windows and without compromising the quality of the material.

After excitation, the deposition species generated in each of the spatially-separated delivery conduits may be transported away from the region of microwave coupling and combined downstream in the vicinity of a substrate for deposition of the amorphous silicon product material. With the deposition apparatus, the high deposition rate advantage afforded by microwave plasma excitation is realized while avoiding: (1) the formation of microwave-absorbing materials on the microwave windows used to transfer the microwave energy needed to energize one or more deposition precursors, and (2) excess formation and incorporation of silanaceous byproducts and other defects in the product film.

The tendency of fluorine to eliminate defects and improve bonding enables deposition of amorphous silicon photovoltaic and semiconducting materials at the high deposition rates available from microwave deposition processes without sacrificing performance. With fluorine, the benefits observed for high hydrogen dilution in slow radiofrequency plasma processes can be achieved at much higher deposition rates in the microwave regime. In contrast to processes based on high hydrogen dilution, a fluorine-based plasma deposition process also produces an amorphous silicon photovoltaic material that is stable against Staebler-Wronski degradation.

The advantages available from fluorine suggest the desirability of maximizing the incorporation of fluorine into amorphous silicon. Incorporation of fluorine into amorphous silicon requires the presence of fluorine in the deposition environment and one would expect that the concentration of fluorine in amorphous silicon would increase as the concentration of fluorine in the deposition environment increases. A precursor such as SiF₄, for example, has a high proportion of fluorine and can be expected to provide a highly fluorinated deposition environment with the ability to supply a high concentration of fluorine to an evolving amorphous silicon product.

There are competing considerations associated with using fluorine, however, that impose practical limits on the amount of fluorine that should be permitted in the deposition environment of amorphous silicon. Fluorine is generally known to be highly reactive and its reactivity is enhanced when activated in a plasma environment. Fluorine is also expected to become more reactive with increasing plasma frequency in PECVD processes. Concerns about high reactivity extend to any fluorinated species present in the deposition environment. Activation of SiF₄ in a plasma, for example, is expected to produce a series of fluorinated species that includes F, SiF, SiF₂, SiF₃, and SiF₄, where the species may be ions, radicals or neutrals. Other precursors, carrier gases, background gases etc. present in the deposition environment may also become fluorinated and exhibit enhanced reactivity when SiF₄ is activated.

A high concentration of reactive fluorine (including free fluorine or fluorinated forms of other species) may be problematic because it can lead to aggressive etching of the deposition surface, the substrate or intervening layers present between the deposition surface and substrate at the time fluorine is introduced into the deposition environment. During deposition, reactive fluorine can also etch the target fluorinated product film. Aggressive etching leads to two detrimental effects. First, overetching can create pinholes or pores that increase the porosity of and undermine the mechanical integrity of one or more layers of the device structure. The presence of a network of pinholes and pores also undermines the electronic properties and chemical stability of the device structure by creating a high internal surface area in the target fluorinated product film and/or underlying layers of the device structure. The high internal surface area includes a high concentration of surface defect states that (1) reduce photovoltaic efficiency through non-radiative recombination processes, and (2) makes the deposition surface or intervening layers susceptible to chemical reaction with environmental agents such as oxygen, nitrogen, or moisture.

A second consequence of aggressive etching is the potential effect of material removed from the deposition surface, underlying layers, or substrate during etching on the deposition process and composition of the device structure. Regarding layers existing on the substrate at the time of introduction of fluorine, etching can alter composition by preferentially removing some elements relative to other elements. Preferential etching can occur because of differences in the relative reactivity of fluorine with respect to different elements. The differential reactivity leads to differences in the rate of removal of different elements from the deposition surface or underlying layers. Differential etching can alter the composition and change the properties of layers in the device structure.

Elements released from the deposition surface or underlying layers can also affect the composition and deposition of the layer being formed at the time of introduction of fluorine and subsequent layers in the device structure. Elements released by etching enter the deposition environment and become available to interact with the prevailing deposition species. Such interactions may affect the mechanism or kinetics of the deposition of the layer being formed at the time elements are released as well as subsequent layers of the device structure.

The elements released by etching also represent a potential source of contaminants. The presence of elements released by etching in the deposition environment makes the elements available for incorporation into newly deposited layers of the device structure. If the elements released by etching are foreign to the intended composition of a depositing layer, contamination results and the characteristics of the layer are altered. In the case of active layers in a photovoltaic device structure, contamination by foreign elements generally introduces electronic defect states in the bandgap, causes irregularities in structure, and reduces efficiency.

The instant inventors believe, however, that a controlled degree of etching by fluorine is beneficial because it facilitates the removal or repair of defects in the active photovoltaic material during deposition. Controlled etching provides a strategy for perfecting the structure of the active photovoltaic material in situ during deposition. As an active photovoltaic material forms, atoms are often incorporated in less-than-optimal configurations that result in irregular coordination, bond strain, and dangling bonds. Distorted or incomplete structural configurations lead to electronic defects that reduce photovoltaic efficiency. With the instant invention, structural irregularities are remedied in real time through the action of fluorine. Structural irregularities are sites of instability in the depositing photovoltaic material and are particularly susceptible to reaction or modification by fluorine. As a result, a persistent, but controlled presence of fluorine in the deposition environment can be effectively employed to preferentially interact with structural irregularities. Through the preferential interaction, fluorine acts primarily on structural irregularities without unduly comprising the integrity of the remaining, more regular structure. The net result is a process in which the presence of fluorine modifies an active photovoltaic layer as it forms by preferentially removing or correcting structural irregularities in real time. As a result, the active photovoltaic material evolves toward a more regular and more defect-free structure during deposition.

Care is required in the utilization of fluorine to realize its reparative benefits without incurring the detrimental effects associated with overly aggressive etching. A careful balance in the activity of fluorine must be struck in order to achieve an improvement in the structure and bonding of an active photovoltaic material in real time while avoiding contamination, damage, and reduction in deposition rate caused by aggressive etching. Through proper management of the activity of the etchant and proper design of the device structure, the restorative benefit associated with etching can be realized and the detrimental effects related to overetching and contamination can be avoided.

One strategy for controlling the degree of etching by fluorine is to manage the presence of fluorine in the deposition environment. The presence of fluorine can be managed by controlling the timing of fluorine introduction, the concentration of fluorine, the reactivity of the precursors used to supply fluorine, the form of fluorine in the deposition environment, and the energetic state or activity of fluorine-containing deposition species.

Hydrogen is another tool for managing the presence of fluorine. The simultaneous presence of hydrogen and fluorine depletes the supply of active, dissociated fluorine through the formation of HF. By binding fluorine with hydrogen, the overall supply of active fluorine can be regulated and controlled to provide enough fluorine to promote favorable bonding configurations within the product thin film while limiting detrimental etching of the product film or underlying layers of the device structure. Proper control of fluorine facilitates formation of a dense, non-porous product film at high deposition rates.

The instant inventors believe that the relative amounts of fluorine and hydrogen can be controlled to promote the successful high speed deposition of high efficiency amorphous silicon in a microwave plasma process. As noted hereinabove, it is desirable to maximize the concentration of fluorine in amorphous silicon product films, but the overabundance or overactivity of fluorine in the growth ambient may promote a detrimental etching effect that increases the porosity and concentration of defect states in the product film. The presence of hydrogen in the product amorphous silicon film can aid in passivating defects, but too much hydrogen may promote the Staebler-Wronski effect. Fluorine and hydrogen can also interact with each other to deplete the concentration of fluorine and/or hydrogen available for incorporation into the product film. Controlled variations in the fluorine and/or hydrogen concentration can also be used to influence the rate of deposition and characteristics of the deposition product by altering the mechanism of the deposition process.

In addition to managing the presence of fluorine, a second strategy for controlling the effect of fluorine on the active photovoltaic material is to incorporate a primer layer into the device structure prior to the introduction of fluorine or other highly reactive deposition species into the deposition environment. A primer layer in accordance with the instant invention is a multi-functional layer that prepares the substrate and/or existing device layers for an aggressive, highly reactive deposition environment. The introduction of fluorine, a fluorinated precursor or other aggressive precursor to the deposition chamber marks the onset of highly reactive deposition conditions that may lead to the etching and contamination effects described hereinabove if not managed or otherwise counteracted.

The primer layer combats the effects of a highly reactive deposition environment. In one embodiment, the primer layer is impervious to the highly reactive deposition environment and remains stable in the presence of fluorine, fluorinated deposition species, or other aggressive, highly reactive deposition species. In another embodiment, the primer layer may be susceptible to etching, degradation or alteration in a highly reactive deposition environment, but is designed to release elements that are not deleterious to the presently or subsequently depositing layers of the device structure. The elements released by the primer layer may be foreign to the presently or subsequently depositing layers, but benign if incorporated therein. Alternatively, the elements released by the primer layer may not be foreign and may instead coincide with constituent elements of the presently or subsequently depositing layers such that their presence does not represent a contamination.

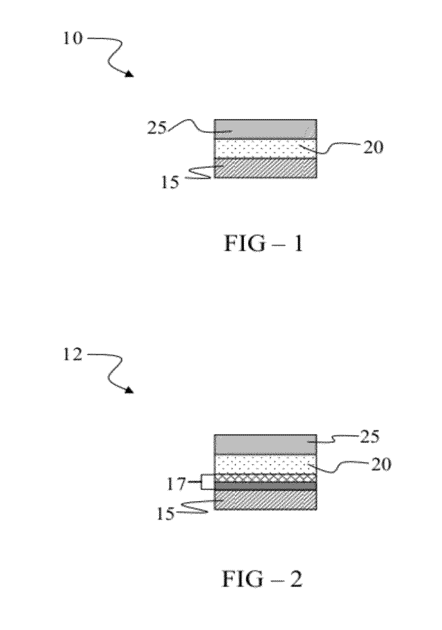

The instant invention provides a device structure with a primer layer. The device structure includes a substrate, a primer layer, and an active layer, where the primer layer is disposed between the substrate and active layer. FIG. 1 depicts one embodiment of a device structure in accordance with the instant invention. Device 10 includes substrate 15, primer layer 20, and active layer 25. In device 10, primer layer 20 is disposed between substrate 15 and active layer 25. During fabrication of device 10, substrate 15 is provided, primer layer 20 is formed on substrate 15, and active layer 25 is formed on primer layer 20.

Substrates in accordance with the instant invention may be discrete or continuous and may be stationary or mobile during deposition. A discrete substrate is generally a substrate that fits within the boundaries of the deposition chamber used to form layers thereon. In one embodiment, a discrete substrate is used in a batch process to form a device structure. In the batch process, the discrete substrate may be stationary while one or more layers are deposited thereon. The discrete substrate may also be mobile and transported through the deposition chamber during deposition. During transport, the discrete substrate may be in continuous motion. Alternatively, the discrete substrate may be in intermittent motion. In an intermittent process, the discrete substrate may be conveyed into the deposition chamber, stopped for deposition, and conveyed out of the deposition chamber after deposition. The process may include a plurality of discrete substrates in continuous or intermittent motion for batch or continuous processing.

A continuous substrate is generally an extended substrate having a dimension that extends beyond the boundaries of the deposition chamber. Continuous substrates include continuous webs and are typically delivered from a payout roller to the deposition chamber and received by a take up roller from the deposition chamber after deposition of one or more layers. Continuous substrates are typically in continuous motion during deposition, but may be stopped or moved intermittently.

Suitable substrate materials include any mechanically durable material capable of supporting a multilayer device structure. Types of substrate materials include metals, metal alloy, plastics, foils, composites, and glass. Representative substrate materials include steel, aluminum, silicon, Kevlar, Mylar, Kapton, Plexiglass, polyimides, polyethylene, quartz, glass and similar materials.

The deposition apparatus may include one or more deposition chambers. In one embodiment, each deposition chamber is equipped to deposit or process a separate thin film layer of the device structure. A multilayer device structure may be formed by advancing a substrate through one or more deposition chambers and depositing a plurality of layers thereon. Methods for forming individual layers include physical vapor deposition (PVD), sputtering, chemical vapor deposition (CVD, MOCVD), evaporation, plasma deposition process (e.g. PECVD), and solution phase deposition (e.g. sol-gel deposition or inkjet deposition).

Primer layer 20 in the device structure of FIG. 1 overlies substrate 15. In the embodiment of FIG. 1, primer layer 20 is in direct contact with substrate 15. In other embodiments, one or more intervening layers may be present between substrate 15 and primer layer 20. Intervening layers may include one or more adhesion layers, conductive layers, transparent conductive oxide layers, semiconducting layers, or combinations thereof. FIG. 2 depicts an embodiment of a device 12 in accordance with the instant invention that includes one or more intervening layers 17 disposed between substrate 15 and primer layer 20.

Primer layer 20 is an integral part of the device structure and serves as an intermediary during fabrication of the device that shields the substrate and/or intervening layers from the deposition environment used to form active layer 25. In one embodiment, primer layer 20 is formed immediately before deposition of active layer 25 and active layer 25 is in direct contact with primer layer 20. The presence of the primer layer permits deposition of active layer 25 with precursors or under conditions that might otherwise damage or modify the substrate or intervening layers. In one embodiment, active layer 25 is formed by a plasma-enhanced chemical vapor deposition (PECVD) process and the deposition environment used to form active layer 25 includes one or more precursors (or fragments thereof) that would etch or otherwise chemically modify the substrate and/or intervening layers in the absence of primer layer 20. Primer layer 20 also protects the substrate and/or intervening layers from physical damage caused by high energy collisions of ions or electrons present in a plasma deposition environment.

In addition to protecting the substrate and/or intervening layers from harsh deposition environments, primer layer 20 serves the dual purpose of protecting active layer 25 from contamination with elements that may be released from the substrate and/or intervening layers through chemical or physical processes that may occur at the deposition conditions used to form active layer 25. In one embodiment, primer layer 20 is stable and impervious to the deposition conditions used to form active layer 25. In another embodiment, primer layer 20 is composed of elements that are compatible with active layer 25. Elements compatible with active layer 25 are elements that do not materially affect the characteristics of active layer 25 if released from primer layer 20 and then incorporated into active layer 25 as it forms. In a further embodiment, primer layer 20 is composed of elements that may be released at the deposition conditions used to form active layer 25, but which are not incorporated in active layer 25.

The desirable characteristics for primer layer 20 depend on the composition of active layer 25 and the deposition conditions used to form active layer 25. In one embodiment, primer layer 20 includes one or more elements in common with active layer 25. In another embodiment, primer layer 20 includes only one or more of the constituent elements of active layer 25. In a further embodiment, primer layer 20 is a non-oxide layer. As used herein, a non-oxide layer is a layer that consists essentially of elements other than oxygen. In one embodiment, the primer layer is a non-oxide layer that comprises silicon (e.g. silicon, a hydrogenated form of silicon, silicon nitride or a nitrogenated form of silicon, silicon carbide or a carbonized form of silicon, or silicon alloy).

Primer layer 20 must be structurally compatible with active layer 25 so that the interface between primer layer 20 and active layer 25 is smooth and regular to avoid or inhibit interfacial defect states that may function as carrier traps. Typically, primer layer 20 is formed under less aggressive conditions than active material 25 to avoid etching or damage to the substrate and/or underlying layers present when primer layer 20 is formed. Elements ejected from the deposition surface during formation of primer layer 20 represent a source of contaminants that may be incorporated into primer layer 20. Such contaminants may subsequently be released at the more aggressive conditions typically used to form active layer 25. In one embodiment, primer layer 20 is formed from a non-fluorinated deposition environment, while active layer 25 is formed from a fluorinated deposition environment. Further discussion of primer layer 20 is presented hereinbelow in connection with specific active materials and in the illustrative examples that follow.

Active layer 25 is generally a layer or material having photovoltaic or semiconducting properties. The structure of the active layer may include an amorphous phase, a nanocrystalline phase, a microcrystalline phase, a polycrystalline phase, or a combination of two or more of such phases. An active layer may also be referred to herein as an active material. A particularly important class of active materials is photovoltaic or semiconducting materials that include silicon. These active materials may include silicon, alloys of silicon with germanium or other elements to achieve bandgap tuning, and silicon-containing materials that include chemical modifiers such as hydrogen and fluorine to control structure and improve performance.

In one embodiment, the active layer is formed in a CVD or PECVD process from a non-hydrogenated precursor. In one embodiment, the PECVD process utilizes microwave plasma excitation. Representative non-hydrogenated precursors for the deposition of amorphous silicon include tetrahalosilanes such as SiF₄ and SiCl₄. Germanium alloys of amorphous silicon may utilize GeF₄ and GeCl₄ as precursors. The deposition process may also include one or more hydrogenated precursors such as H₂, SiH₄, Si₂H₆, and GeH₄ as well as fluorine gas, NF₃ or other non-silicon containing fluorinated gas, hydrogen fluoride gas, and/or carrier or background gases such as argon, helium, krypton, or neon. Deposition species may also include precursors designed to achieve n-type or p-type doping. Doping precursors include gas phase compounds of boron (e.g. boranes, organoboranes, fluoroboranes), phosphorous (e.g. phosphine, organophosphines, or fluorophosphines), arsenic (e.g. arsine or organoarsines), and SF₆. One or more deposition or doping precursors may be introduced individually, sequentially, or in combination.

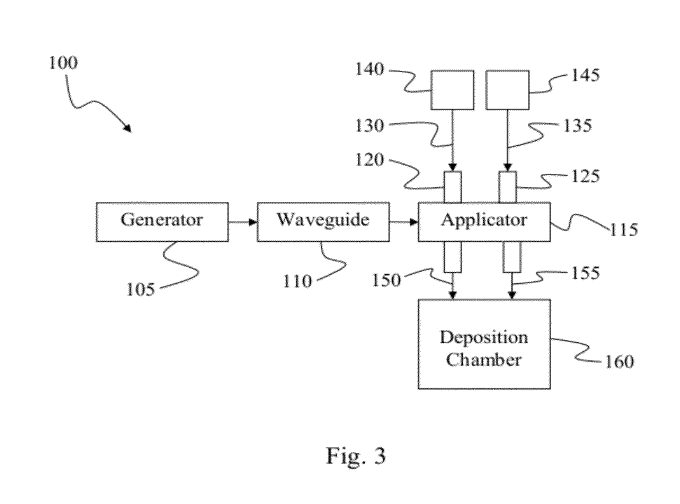

As noted hereinabove, it may be desirable to maintain a physically separation of non-hydrogenated and hydrogenated deposition precursors in the plasma excitation region of the deposition chamber to avoid interactions between silicon and hydrogen. A representative microwave deposition system that achieves physical separation of two or more streams of deposition precursors is shown schematically in FIG. 3. System 100 includes microwave generator 105 that creates a field of microwave radiation and launches it through microwave waveguide 110 to microwave applicator 115. Microwave generator 105 typically includes a magnetron and delivers a field of microwave radiation at a single frequency (e.g. 915 MHz, 2.45 GHz, 5.8 GHz). Applicator 115 couples the microwave radiation to deposition species passing through conduits 120 and 125. Conduit 120 receives one or more deposition species in stream 130 from source 140 and conduit 125 receives one or more deposition species in stream 135 from source 145. The microwave radiation couples to deposition species provided to conduits 120 and 125 to produce streams 150 and 155, respectively, containing energized deposition species that are delivered to deposition chamber 160 for formation of a thin film.

Although not shown, the deposition system may further include an isolator directly after microwave generator 105 to protect it from back-reflected microwave radiation. The isolator includes a circulator and a dummy load to neutralize back-reflected microwaves. The deposition system may also include a directional coupler in the waveguide run to detect and monitor forward and reflected microwave power, and a tuner to match the impedance of the load with the impedance of the source. Adjustment of the tuner minimizes the reflected power level. A termination device or sliding short circuit may also be connected to the downstream end of the applicator to assist with impedance matching or to establish a standing wave condition that maximizes microwave power in the vicinity of the conduits to increase the transfer of microwave power to the deposition species.

Applicator 115 may include two or more conduits for delivering deposition species to a region of microwave coupling (power transfer). The conduits provide for physical separation of two or more streams containing deposition precursors, while permitting simultaneous microwave excitation of the individual streams. The conduits receive deposition species from a source and transport them to an interior cavity of the applicator for coupling to the microwave radiation provided by waveguide 110. The coupling transfers energy from the microwave radiation to the deposition species to activate or otherwise energize them to a high energy state. The energized deposition species are then delivered by the conduits to the deposition chamber for deposition of a thin film material.

The high energy state created by transfer of microwave power is a reactive state and enhances reactions between deposition species. The rates of reactions between deposition species that occur in a non-energized state are generally increased when the deposition species are placed in an energized state and reactions that do not otherwise occur between deposition species may be induced in the plasma-energized state. Physical separation of the deposition species by the conduits provides the benefit of preventing reactions between deposition species in the region where microwave power (or energy) is transferred to the deposition species. As a result, the formation of thin film coating or deleterious deposition species (e.g. polysilanes, silicon dihydride radicals) in the region of power transfer is avoided.

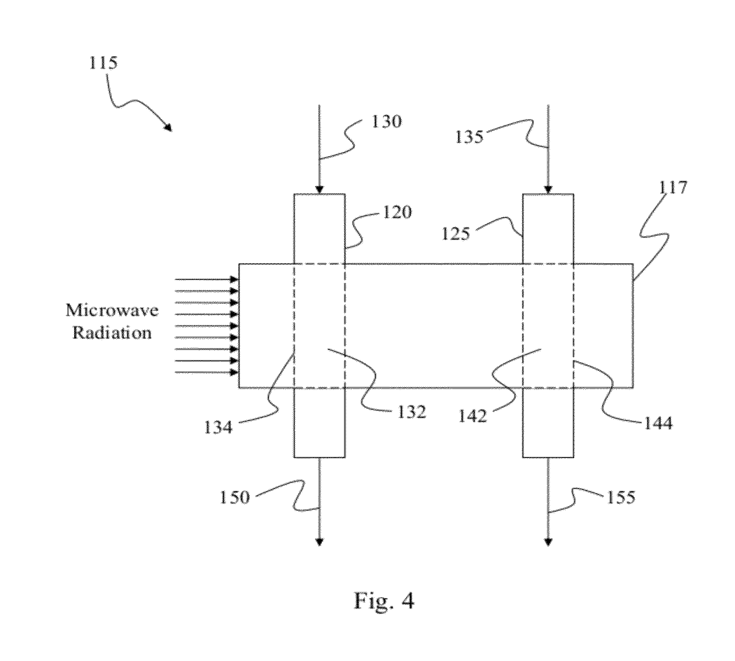

FIG. 4 shows an enlargement of applicator 115 in side view. Microwave radiation from waveguide 110 enters cavity 117, which couples microwave radiation to the deposition species in streams 130 and 135. In particular, cavity 117 is configured to transfer microwave power or energy to the deposition species in streams 130 and 135 in regions 132 and 142, respectively. Regions 132 and 142 correspond to the regions of transfer of microwave power (or energy) to streams 130 and 135, respectively, and coincide with the interior portions of conduits 120 and 125, respectively, that pass through the interior of applicator 115.

Microwave transfer region 132 includes boundary or window 134 that transmits microwave radiation through conduit 120 to deposition species in stream 130. Microwave transfer region 142 includes boundary or window 144 that transmits microwave radiation through conduit 125 to deposition species in stream 135. Transfer of microwave power (or energy) to deposition species in stream 130 produces energized deposition species that exit applicator 115 in stream 150. Transfer of microwave power (or energy) to deposition species in stream 135 produces energized deposition species that exit applicator 115 in stream 155.

Physical separation of streams 130 and 135 in the region of microwave power (or energy) transfer prevents reactions between energized deposition species in stream 150 and energized deposition species in stream 155 that might otherwise occur to form a coating on the conduit windows. By delaying the interaction of the energized deposition species in streams 150 and 155 until after delivery into deposition chamber 160, the formation of a thin film material occurs away from the region of microwave power (or energy) transfer and the coating of conduit windows is avoided. The delayed interaction between the energized deposition species in streams 150 and 155 may also diminish the tendency of species within streams 150 and 155 to form undesirable (non-solid phase) intermediates in the deposition environment.

Conduits 120 and 125 are formed from a material that transmits microwave radiation. Preferably, conduits 120 and 125 are highly transparent to microwave radiation. Dielectric materials, such as oxides and nitrides, are among the dielectric materials that may be used to form conduits 120 and 125. Representative dielectric materials include SiO₂, quartz, Al₂O₃, sapphire, transition metal oxides, silicon nitride, aluminum nitride, and transition metal nitrides.

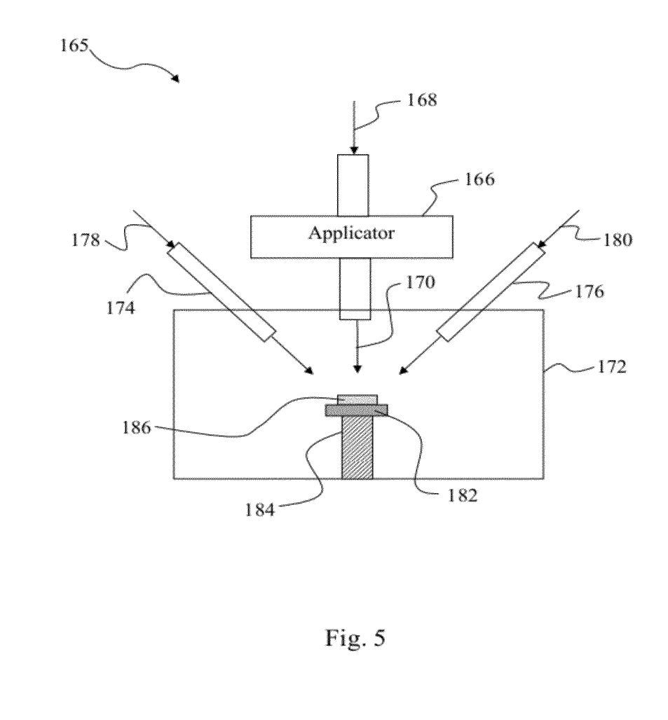

FIG. 5 depicts an embodiment of the deposition apparatus in which supplemental material streams are directed to the deposition chamber in combination with an energized deposition medium. System 165 includes microwave applicator 166 that receives input stream 168 and energizes it with microwave radiation to form energized deposition medium 170 that is delivered to deposition chamber 172. Input stream 168 may include one or more components, where each component is a deposition precursor, intermediate, carrier gas, or diluent gas. System 165 further includes inlets 174 and 176 that deliver supplemental material streams 178 and 180 to deposition chamber 172. Supplemental material streams 178 and 180 may be precursors, intermediates, carrier gases, diluent gases, or background gases and are directly delivered to deposition chamber 172 without being activated or energized in microwave applicator 166. Supplemental material streams 178 and 180 combine with energized deposition medium 170 in the vicinity of substrate 182 positioned on mount 184. Supplemental material streams 178 and 180 interact, dilute, or react with energized deposition medium 170 at or on substrate 182 to form thin film material 186. Transfer of energy may also occur between energized deposition medium 170 and supplemental material streams 178 and 180. Energized deposition medium 170 may, for example, excite or energize supplemental material streams 178 and 180. Supplemental material streams may be delivered through inlets coupled to the deposition chamber or through internal structures within the deposition chambers such as a ring, manifold or showerhead.

The embodiment shown in FIG. 5 depicts a deposition system that includes two supplemental material streams in combination with a microwave applicator that provides a single microwave-energized deposition medium stream. In related embodiments, the microwave applicator may provide two or more microwave-energized deposition medium streams or two or more microwave applicators, each of which provides one or more microwave-energized deposition medium streams may be employed. The number of supplemental streams may be one or more.

The relative amounts of non-hydrogenated (e.g. SiF₄) and hydrogenated (e.g. H₂, SiH₄, Si₂H₆) deposition streams may be adjusted by controlling the pressure or flow rate of each in their respective conduits or by combining either or both of the non-hydrogenated and hydrogenated deposition streams with a carrier or background gas. Inclusion of deposition species such as F₂ or HF provide further control over the relative amounts of silicon, hydrogen and fluorine present in the deposition environment that prevails in the vicinity of the substrate. Adjustment of the relative amounts of deposition species containing silicon, germanium, hydrogen, and/or fluorine permits control over the degree of crystallinity and microstructure of the thin film material deposited on the substrate as well as control over the density of states and severity of the Staebler-Wronski effect.

In other embodiments, a fluorine-containing gas and a hydrogen-containing gas may be delivered by separate conduits of one or more microwave applicators. SiF₄ and SiH₄, for example, may be delivered by separate conduits of a microwave applicator. Similarly, SiH₄ and a fluorine-containing gas (e.g. F₂, NF₃, or a fluorinated germanium gas) may be delivered by separate conduits of one or more microwave applicators.

In still other embodiments, one or more of a silicon-containing gas, germanium-containing gas, fluorine-containing gas, or hydrogen-containing gas may be delivered by a microwave applicator as an energized deposition medium to a deposition chamber and one or more additional silicon-containing gases, germanium-containing gases, fluorine-containing gases, or hydrogen-containing gases may be delivered as supplemental material streams to the deposition chamber. For example, one or more of SiF₄, SiH₄, Si₂H₆, H₂, or F₂ may be delivered by a microwave applicator as an energized deposition medium to a deposition chamber and others of SiF₄, SiH₄, H₂, Si₂H₆ or F₂ may be delivered as supplemental material streams to the deposition chamber. As indicated hereinabove, the supplemental material streams are introduced to the deposition chamber without having first been excited by microwave radiation. The supplemental material streams may then combine with the microwave-energized deposition species entering the deposition chamber from one or more conduits that have been exposed to microwave radiation outside of the deposition chamber.

In one embodiment, SiF₄ is activated by microwave energy in a conduit of an applicator and delivered to a deposition chamber equipped to provide H₂ as a supplemental material stream, where the H₂ stream has not been activated by microwave radiation before entering the deposition chamber. In another embodiment, SiF₄ is activated by microwave energy in a conduit of an applicator and delivered to a deposition equipped to provide SiH₄ as a supplemental material stream, where the SiH₄ stream has not been activated by microwave radiation before entering the deposition chamber. In other embodiment, fluorine is provided both in a supplemental, non-energized material stream and as a microwave-energized material stream from an applicator. The supplemental fluorine stream may include F₂, NF₃ or HF diluted by a carrier gas such as a noble gas. The supplemental fluorine stream may also include SiF₄ or other fluorinated form of silane or disilane.

### Example 1

In this example, selected photovoltaic characteristics of device structures in accordance with the instant invention are described. A series of sample devices was prepared with a deposition apparatus similar to the one depicted in FIG. 5. The deposition apparatus included a single microwave applicator with a single conduit passing therethrough and a single supplemental inlet for delivering a non-energized supplemental material stream. The conduit was made from sapphire and the substrate was positioned about 4 inches from the interface of the conduit with the deposition chamber. Each sample had the structure shown in FIG. 1 and included a substrate, a primer layer, and an active layer. The substrate for each sample was quartz and similar results have been obtained using glass substrates. The primer layer was formed directly on the substrate and the active layer was formed directly on the primer layer. The deposition rates of the primer layer and active layers were approximately 30 Å/s and 250 Å/s, respectively.

To form the primer layer, a mixture of 1 standard liter per minute of H₂ and 3 standard liters per minute of argon was introduced to the conduit of the microwave applicator and activated with microwave radiation at a frequency of 2.45 GHz and a power of 600 W. SiH₄ was introduced at a rate of 1 standard liter per minute to the deposition chamber through the supplemental delivery port. The supplemental SiH₄ stream was added directly to the deposition chamber and was not passed through the region of microwave excitation in the applicator. The energized stream exiting the conduit of the microwave applicator and the non-energized supplemental stream were directed to the substrate to deposit the primer layer. The substrate was maintained at a temperature of about 260° C. during deposition of the primer layer. With the selected deposition conditions, the primer layer was primarily amorphous silicon with some degree of hydrogenation.

To form the active layer, a mixture of 1 standard liter per minute of SiF₄ and 2 standard liters per minute of argon was introduced to the conduit of the microwave applicator and activated with microwave radiation at a frequency of 2.45 GHz and a power of 600 W. SiH₄ was introduced at a rate of 1 standard liter per minute to the deposition chamber through the supplemental delivery port. The supplemental SiH₄ stream was added directly to the deposition chamber and was not passed through the region of microwave excitation in the applicator. The energized stream exiting the conduit of the microwave applicator and the non-energized supplemental stream were directed to the substrate to deposit the active layer directly on the primer layer. The substrate was maintained at a temperature of about 390° C. and during deposition of the active layer. With the selected deposition conditions, the active layer was primarily a fluorinated and hydrogenated form of amorphous silicon.

A series of samples was prepared in which the thickness of the primer layer was varied. Samples 945 and 946 were control samples that were prepared without a primer layer. Additional samples having primer layers with thicknesses varying from 31 nm to 372 nm were prepared. The thickness of the primer layer in each of the samples is listed in the table below. The active layer of samples 946, 947, and 948 had a thickness of 1 μm. The thickness of the active layer in the remaining samples was 0.5 μm.

To assess the effect of the primer layer on the photovoltaic characteristics, the μτ product of the active layer was measured for each sample upon incident photoexcitation at two above bandgap wavelengths (565 nm and 660 nm). The μτ product is the product of the mobility (μ) and lifetime (τ) of photogenerated charge carriers. The μτ product provides an assessment of the defect concentration of the active material and is known in the art to correlate with the photoconductivity of each sample. A higher value for the μτ product indicates better photoconductivity and a higher quality material.

The presence of defects deteriorates the quality of the material by providing trap states that capture photogenerated carriers and reduce carrier mobility. The presence of defect states increases the rates of trapping and recombination of photogenerated charge carriers in the active material and result in a decrease in both carrier mobility and carrier lifetime. High quality photovoltaic materials have a low concentration of defects states and exhibit high carrier mobility and high carrier lifetime. High carrier mobility and high carrier lifetime increase the likelihood that photogenerated carriers created in the interior of the active material are transported to electrical contacts at the surface of the material for delivery to an external load without being depleted by defect states. As a result, photovoltaic efficiency is improved. The μτ product (expressed in units of cm²/V) of each of the samples at both excitation wavelengths is included in the table below.

| | Primer Layer | | |
|---|---|---|---|
| Sample | Thickness (Å) | μτ (565 nm) | μτ (660 nm) |
| 921 | 620 | 4.08E−08 | 4.52E−08 |
| 928 | 620 | 2.66E−07 | 2.33E−07 |
| 929 | 1240 | 7.05E−06 | 7.25E−06 |
| 931 | 310 | 1.79E−09 | 3.23E−09 |
| 945 | 0 | 2.06E−09 | 2.48E−09 |
| 946 | 0 | 5.66E−08 | 5.19E−08 |
| 947 | 620 | 1.12E−08 | 1.35E−08 |
| 948 | 1240 | 1.62E−07 | 1.21E−07 |
| 949 | 1240 | 1.59E−07 | 4.15E−07 |
| 950 | 1860 | 3.76E−06 | 1.49E−05 |
| 951 | 930 | 1.18E−08 | 1.74E−08 |
| 952 | 1550 | 3.66E−07 | 6.67E−07 |

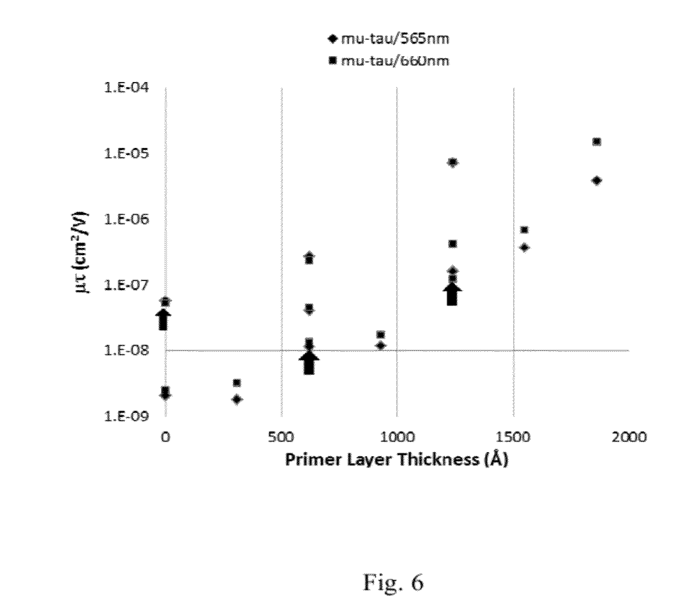

FIG. 6 shows the variation in μτ product with the thickness of the primer layer for the series of samples. The three samples with the 1 μm thick active layer are marked with an arrow. The results show a clear increase in μτ product with increasing primer layer thickness. The low μτ product observed for control sample 945 indicated that the fluorinated plasma deposition conditions used to form the active layer interacted with the substrate to produce an active layer with poor carrier mobility and carrier lifetime. As described hereinabove, fluorinated plasma deposition conditions are highly reactive and can etch or otherwise alter the substrate during deposition. Etching may release elements from the substrate that ultimately contaminate the active layer of sample 945. Interaction of the fluorinated plasma with the substrate may also damage the surface of the substrate to provide a low quality interface between the substrate and the active layer of sample 945. A low quality interface is expected to include a high concentration of defect states that can serve as carrier trapping or recombination centers that act to reduce carrier mobility and/or carrier lifetime.

The presence of the primer layer shields the substrate from the potentially aggressive, highly reactive conditions of the fluorinated plasma used to form the active layer. The influence of the substrate on the characteristics of the active layer is expected to become increasingly attenuated as the thickness of the primer layer increases. The results shown in FIG. 6 are consistent with this expectation. Only slight improvement in the μτ product was observed when the primer layer was thin (sample 931), but an increasingly pronounced improvement in μτ product was observed in samples having thicker primer layers. The μτ product of sample 950 was more than three orders of magnitude greater than the μτ product of control sample 945.

In one embodiment, the primer layer has a thickness of at least 100 Å. In another embodiment, the primer layer has a thickness of at least 300 Å. In still another embodiment, the primer layer has a thickness of at least 600 Å. In yet another embodiment, the primer layer has a thickness of at least 1200 Å. In a further embodiment, the primer layer has a thickness of at least 1500 Å. In still a further embodiment, the primer layer has a thickness of at least 1800 Å.

The data also suggest trends in the dependence of the μτ product on the thickness of the primer layer. Samples 945 and 946 correspond to samples without a primer layer that differed in the thickness of the active layer. Sample 946 had an active layer thickness of 1 μm and sample 945 had an active layer thickness of 0.5 μm. The results indicated that sample 946 had a higher μτ product than sample 945. Sample 921, sample 928 and sample 947 each had a primer layer with a thickness of 620 Å, but differed in the thickness of the active layer. Sample 947 had an active layer thickness of 1 μm, while sample 921 and sample 928 each had an active layer thickness of 0.5 μm. The results indicated that samples 921 and 928 each had a higher μτ product than sample 947. Sample 929, sample 948 and sample 949 each had a primer layer with a thickness of 1240 Å, but differed in the thickness of the active layer. Sample 948 had an active layer thickness of 1 μm, while sample 929 and sample 949 each had an active layer thickness of 0.5 μm. The results indicated that samples 929 and 949 each had a higher μτ product than sample 948.

The data indicate that when the primer layer is absent, the μτ product increased with increasing thickness of the active layer, but when a primer layer is present, the μτ product decreased with increasing thickness of the active layer. While not wishing to be bound by theory, the instant inventors suggest that the difference in the thickness dependence for samples with and without a primer layer may be related to the relative rates of etching and deposition of the substrate, primer layer, and/or active layer.

As described hereinabove, deposition of an active layer from a deposition environment that includes an element reactive with the deposition surface is expected to remove elements from the deposition surface and transfer them to the deposition environment to make them available for incorporation into the active layer. When the deposition surface is the substrate surface and the substrate surface includes elements that contaminate the active layer, one would expect contamination of the active layer. As the active layer forms, however, it coats the substrate surface and provides a buffer between the growth surface and the substrate surface that inhibits further release of elements from the substrate surface. As a result, the contaminant concentration of the active layer is expected to be non-uniform. A higher contaminant concentration is expected near the interface of the active layer with the substrate and a progressively lower contaminant concentration is expected with increasing distance from the interface. Since the overall contaminant concentration is thus expected to decease as the thickness of the active layer increases and a higher μτ product accordingly results.

In device structures having a primer layer, the primer layer is in place at the time that deposition of the active layer is initiated and forms the deposition surface. Based on the deposition conditions used for the data of this example, it is expected that the primer layer will consist primarily of a hydrogenated form of amorphous silicon. The presence of fluorine in the deposition environment of the active layer is expected to etch or otherwise react with an amorphous silicon primer layer. The fluorinated deposition environment is also expected to etch the active layer itself as it is depositing so that the net rate of formation of the fluorinated amorphous silicon active layer reflects a balance between the rate of etching of the active layer and the rate of formation of the active layer. The high net rate of deposition noted hereinabove indicates that the balance is tipped sharply in favor of the rate of formation. The rate of etching is believed to be high enough to remove or repair defective structural configurations, but not so high that detrimental overetching occurs.

The possibility that the fluorinated deposition environment used in the formation of the active layer can etch the primer layer, however, may influence the presence or distribution of contaminants in the active layer. If the primer layer is thin, for example, a tendency of the fluorinated deposition environment to etch the primer layer creates a possibility that the primer layer may be penetrated (at least locally and perhaps only momentarily) to expose the substrate to the deposition environment. If the substrate is exposed, it too may be etched and may accordingly release contaminants into the deposition environment. As indicated hereinabove, such contaminants may become incorporated into the active layer and the μτ product may be compromised as a result.

A possible explanation of the observed reduction in μτ product with increasing thickness of the active layer at fixed primer layer thickness is that thicker active layers necessarily expose the primer layer to the aggressive fluorinated deposition condition for a longer period of time. The increased time of exposure may create channels or pathways through some portion of the primer layer that expose the substrate and thus increase the likelihood of contamination of the active layer. The channels or pathways may only be transient and may ultimately be covered or blocked upon continued deposition of the active layer, but even temporary exposure of the substrate to an etchant may lead to contamination.

This example shows that inclusion of a primer layer in the structure of an amorphous silicon photovoltaic device improves the transport properties (as assessed by the μτ product) of photogenerated charge carriers. The active layer of the devices of this example was formed at a high deposition rate using a microwave plasma process and a fluorinated deposition environment. The beneficial effect of fluorine in improving the structure and bonding of amorphous silicon and in eliminating defects in amorphous silicon was realized without countervailing contamination effects resulting from interaction of the fluorinated deposition environment with the substrate. The presence of the primer layer prevented or minimized interactions between the highly reactive fluorinated plasma environment used to deposit the active layer. Instead of acting on the substrate, the high reactive fluorinated plasma acted on the primer layer. Since the primer layer was composed of elements desired in the active layer, any elements released from the primer layer by the fluorinated plasma had a benign effect on the active layer.

The low density of states and superior electrical transport properties of the instant device structures have utility beyond photovoltaics and extend to a broader array of electronic applications. The instant device structures, for example, provide excellent prospects for transistors and diodes based on amorphous silicon. The instant invention motivates a true silicon-based thin film electronics technology and is not limited only to photovoltaic technology.

The beneficial effects further extend beyond silicon to other materials. The instant invention addresses the general problem of wishing to avoid an accumulation of defects in an active material at high deposition rates. By managing the presence of fluorine (or other reactive, etching species) and/or utilizing a primer layer in accordance with the principles of the instant invention, formation of defects in a wide variety of materials can be suppressed. Fluorine is reactive toward most material compositions and can perform the function of removing and/or repairing structural irregularities on a generally universal basis. In addition to silicon, materials based on elements from column III (Ga, In), column IV (germanium, tin, carbon), column V (As, P), VI (Te, Se), and transition metals are expected to benefit from the principles of the instant invention. Representative materials include GaAs, InAs, SiC, Ge, CdTe, CIGS alloys, and grapheme.

### Example 2

In this example, the measurement of the wavelength dependence of the quantum efficiency of a device structure in accordance with an embodiment of the instant invention is presented. The sample was prepared as described hereinabove in Example 1 and may be referred to as sample 944. Sample 944 included a primer layer with a thickness of 3720 Å and an active layer with a thickness of 0.5 μm. As noted hereinabove, the primer layer was composed primarily of a hydrogenated form of amorphous silicon and the active layer was composed primarily of a hydrogenated and fluorinated form of amorphous silicon.

Quantum efficiency is a measure of the photoconversion efficiency of a photovoltaic device and corresponds to the number of productive charge carriers generated per photon incident to the photovoltaic device. Productive charge carriers are the subset of photogenerated charge carriers that are transported to electrical contacts at the surface of the active photovoltaic material for delivery to an external circuit. Unproductive charge carriers are the subset of photogenerated charge carriers that fail to reach the electrical contacts due to recombination, trapping, scattering, or other loss process between the point of generation of the charge carrier and the surface electrical contact. In devices with a high quantum efficiency, a high fraction of photogenerated charge carriers arrives at the surface electrical contacts and is available for delivery to an external load.

In this example, quantum efficiency was obtained from a measurement of the photocurrent of sample 944 as a function of excitation energy. The photocurrent is proportional to the product of the photon flux, illumination area, absorbance and quantum efficiency. Photon flux was known from the characteristics of the diode light source employed for the experiment. The illumination area was fixed by the configuration of the experiment and held constant and the absorbance was measured independently.

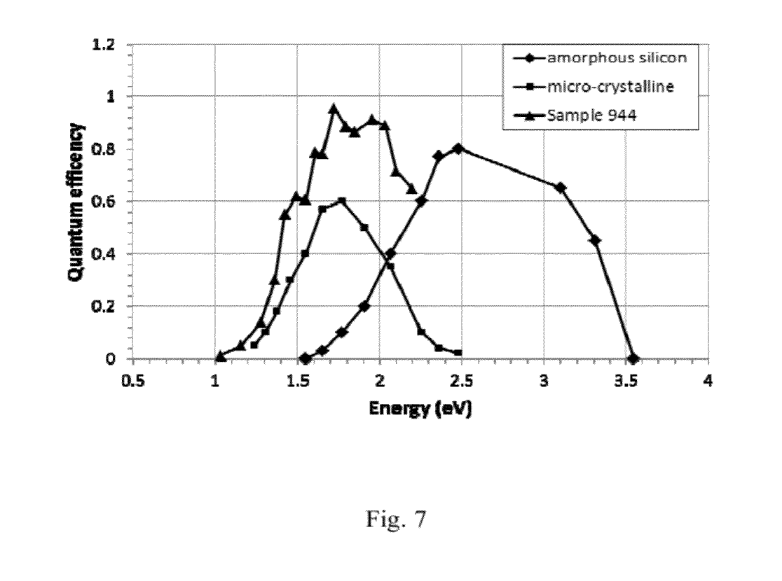

The normalized quantum efficiency of the sample device as a function of photoexcitation energy is shown in FIG. 7. The data for sample 944 are depicted with triangle symbols that are connected with a line to aid visualization. FIG. 7 further includes quantum efficiency data for reference samples of microcrystalline silicon (square symbols) and conventional amorphous silicon (diamond symbols) obtained from an independent source. The data show that that the general dependence of the quantum efficiency of sample 944 on wavelength was similar to that observed for microcrystalline silicon and distinct from that observed for conventional amorphous silicon.

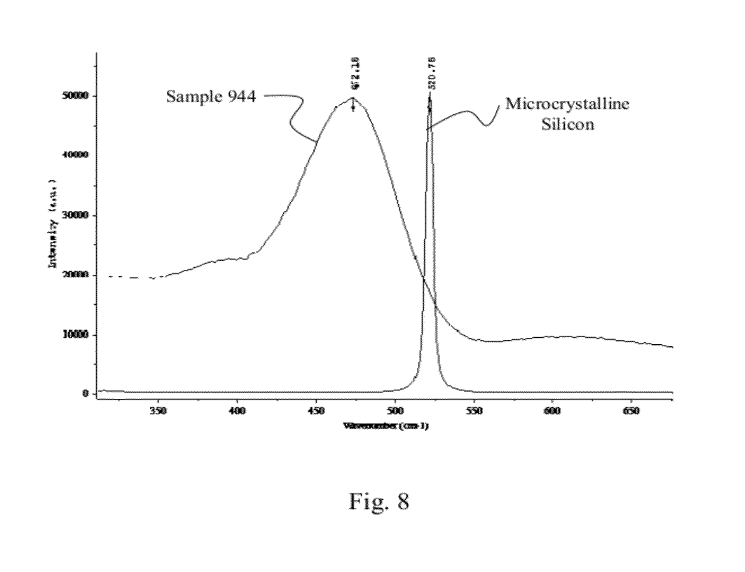

FIG. 8 shows the Raman spectrum of sample 944 along with a comparative Raman spectrum for microcrystalline silicon. A Raman spectrum provides information about the molecular vibrations of the atoms that compose a material. Microcrystalline silicon is known to have a sharp Raman peak at ˜520 cm⁻¹, while conventional amorphous silicon is known to have a broad Raman peak at ˜470 cm⁻¹.

The data shown in FIG. 7 and FIG. 8 lead to the remarkable result that the active photovoltaic material of sample 944 has a generally disordered structure like conventional amorphous silicon (but with a greatly reduced concentration of structural and electronic defects), while at the same time exhibiting optical characteristics similar to those of microcrystalline silicon. Although the structure of sample 944 is reminiscent of conventional amorphous silicon, the optical characteristics are quite distinct from those of conventional amorphous silicon. The superior optical (and photovoltaic) characteristics of the instant materials include low native defect concentration, little or no Staebler-Wronski degradation, high quantum efficiency, and high μτ product and are likely predicated on phenomena normally associated with microcrystalline silicon. The microcrystalline-like optical and photovoltaic characteristics are inherent to the instant materials and the tendency of the material to avoid the formation of defects greatly facilitates the deposition process and underlies the tremendous increase in deposition rate afforded by the instant invention. The instant invention in effect leads to a deconvolution of the structural and optical (or photovoltaic) characteristics of photovoltaic materials and provides a fundamentally new class of photovoltaic materials, operating according to new physics, that allows for the practical realization of the best properties of conventional amorphous and conventional materials.

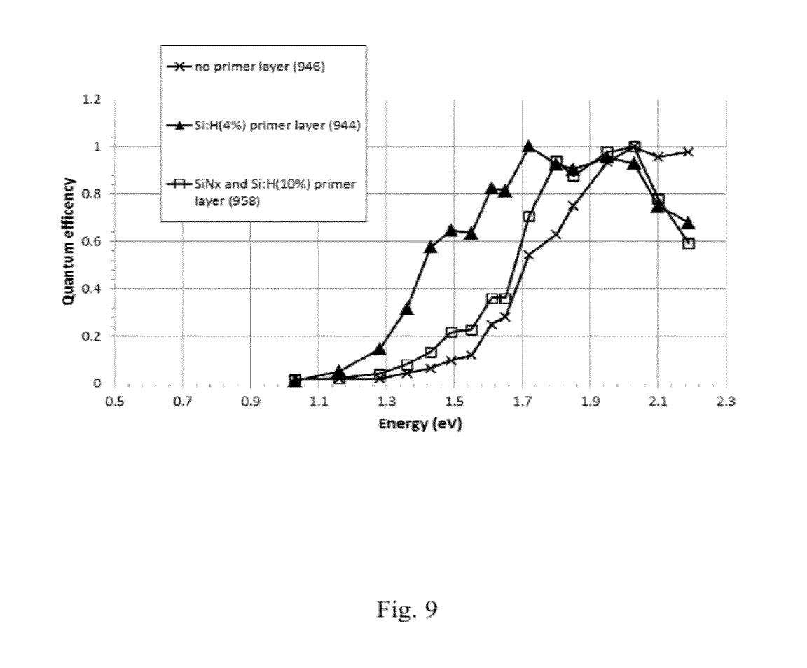

FIG. 9 reproduces the quantum efficiency data shown in FIG. 7 for sample 944 (triangle symbols) and includes quantum efficiency measurements for two additional samples: 946 (cross symbols) and 958 (open square symbols). Sample 946 included an active layer formed under the same conditions as the active layer of sample 944, but lacked a primer layer. Sample 958 also included an active layer formed under the same conditions as the active layer of sample 944 and further included a primer layer composed of a combination of silicon nitride and hydrogenated amorphous silicon.

The results shown in FIG. 9 indicate that the dependence of quantum efficiency on excitation energy can be controlled through the selection of primer layer. In particular, the energy corresponding to peak quantum efficiency and range of excitation energy over which appreciable quantum efficiency was observed can be varied through the inclusion or exclusion of primer layer and/or choice of primer layer. Sample 946 lacked a primer layer and showed a quantum efficiency response that was shifted furthest toward higher excitation energy. The quantum efficiency response of sample 944 was shifted furthest toward lower excitation energy and the quantum efficiency response of sample 958 was intermediate.

The quantum efficiency data shows that the energy range of optimum performance of the instant active photovoltaic materials can be influenced through selection of the primer layer. Samples 944, 946 and 958 included active photovoltaic layers prepared under the same nominal deposition conditions and yet exhibited significantly different dependences of quantum efficiency on excitation energy.

In one embodiment, the active photovoltaic material of this invention comprises amorphous silicon and has a peak quantum efficiency at an excitation energy between 1.5 eV and 2.3 eV. In another embodiment, the active photovoltaic material of this invention comprises amorphous silicon and has a peak quantum efficiency at an excitation energy between 1.6 eV and 2.1 eV. In a further embodiment, the active photovoltaic material of this invention comprises amorphous silicon and has a peak quantum efficiency at an excitation energy between 1.7 eV and 2.0 eV.

The data shown in FIG. 9 further demonstrates that the bandgap tuning common to tandem and triple junction photovoltaic cells can be achieved with an active layer deposition process that utilizes a common set of precursors. In tandem and triple junction cells based on conventional amorphous silicon, it is necessary to alloy with germanium to modify the bandgap to achieve maximum overall efficiency over a series combination of p-i-n devices. With the instant invention, the need for alloying is eliminated.

In one embodiment, the instant invention provides a multilayer photovoltaic device that includes two or more fluorinated active layers. The multilayer photovoltaic device may further include two or more primer layers. In one embodiment, the primer layers are non-fluorinated. In another embodiment, the instant invention provides a multilayer photovoltaic device that includes three or more fluorinated active layers. Any or all of the fluorinated active layers and non-fluorinated primer layers may include silicon. In one embodiment, the fluorinated active layers are intrinsic semiconducting layers. Based on the quantum efficiency results, multilayer photovoltaic devices incorporating two or more active materials in accordance with the instant invention are expected to have an overall cell efficiency of at least 15% and multilayer photovoltaic devices incorporating three or more active materials in accordance with the instant invention are expected to have an overall cell efficiency of at least 20%. Further embodiments of multilayer photovoltaic device structures are presented hereinbelow.

The foregoing discussion and example demonstrate that the instant invention permits realization of the benefits of a highly reactive plasma environment without incurring countervailing detrimental effects caused by etching or contamination from a substrate or underlying layers of a device structure. The advantages of a primer layer extend generally to any highly reactive deposition environment that has the potential to etch or otherwise modify a substrate or underlying layers of a device structure. Although the invention has particular utility to plasma deposition processes because of the inherent reactivity of the plasma state of matter, it applies more generally to any deposition technique that presents a deposition environment conducive to etching, damaging, or modifying a substrate or other layers of a device structure.

Of particular interest as one embodiment of the instant invention is the realization of the benefits of fluorine, including the combined benefits of fluorine and hydrogen, in the fabrication of photovoltaic devices based on active layers of amorphous and/or other structural forms of silicon. As noted hereinabove, both hydrogen and fluorine passivate dangling bonds and relieve bond strain. Since the bond strengths of hydrogen and fluorine with silicon differ, however, hydrogen and fluorine may exhibit a preferential effectiveness for remediating energetically distinct defects within the spectrum of defects known to exist in the various structural forms of silicon (amorphous, intermediate range order, nanocrystalline, and microcrystalline). As a result, material of particularly high quality can be expected through the combined effects of fluorine and hydrogen. With this invention, such material can be formed continuously at high deposition rates in a microwave plasma deposition process without deleterious contamination or interference from a substrate or other layers of a device structure. Unique bonding configurations that minimize the density of states and suppress the Staebler-Wronski effect can be achieved in silicon-based photovoltaic materials through careful control of the relative amounts of hydrogen and fluorine. This invention permits such control at exceptionally high deposition rates.

In one embodiment, the atomic concentration of fluorine in a silicon-containing photovoltaic material is between 0.1% and 7%. In another embodiment, the atomic concentration of fluorine in a silicon-containing photovoltaic material is between 0.2% and 5%. In a further embodiment, the atomic concentration of fluorine in a silicon-containing photovoltaic material is between 0.5% and 4%. In one embodiment, the atomic concentration of fluorine is as indicated above and the atomic concentration of hydrogen is between 1% and 8%. In another embodiment, the atomic concentration of fluorine is as indicated above and the atomic concentration of hydrogen is between 2% and 6%. In a further embodiment, the atomic concentration of fluorine is as indicated above and the atomic concentration of hydrogen is between 3% and 5%.

The instant invention may be used to form photovoltaic and semiconducting devices based on amorphous, nanocrystalline, microcrystalline, or polycrystalline materials, or combinations thereof as a single layer or in a multiple layer structure. In one embodiment, the instant deposition apparatus includes a plurality of deposition chambers, where at least one of the deposition chambers provides a primer layer in accordance with the instant invention. The different chambers may form materials of different composition, different doping, and/or different crystallographic form (amorphous, nanocrystalline, microcrystalline, or polycrystalline).

The instant device structure may be fabricated on a continuous web or other moving substrate. In one embodiment, a continuous web substrate or other moving substrate is advanced through each of a plurality of deposition chambers and a sequence of layers is formed on the moving substrate. The individual deposition chambers within the plurality are operatively interconnected and environmentally protected to prevent intermixing of the deposition species introduced into the individual chambers. Gas gates, for example, may be placed between the chambers to prevent intermixing. A variety of multiple layer or stacked cell device configurations may be obtained.

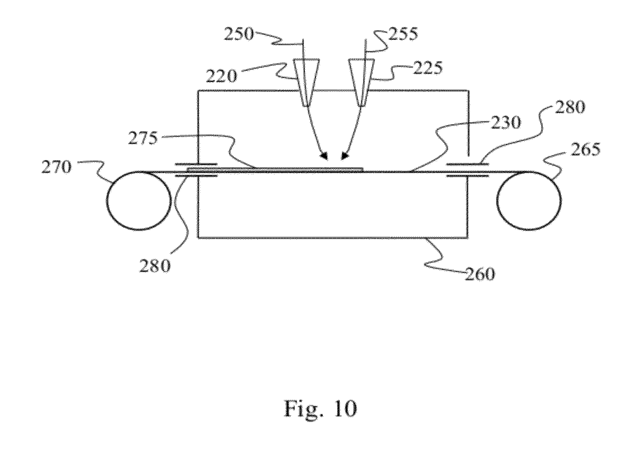

FIG. 10 shows a portion of a deposition system in accordance with the instant invention that includes a continuous web substrate. The deposition system includes deposition chamber 260 equipped with continuous web substrate 230. Continuous web substrate 230 is in motion during deposition and is delivered to deposition chamber 260 by payout roller 265 and received by take up roller 270 after deposition of thin film material 275. Continuous web substrate 230 enters and exits deposition chamber 260 through isolation devices 280. Isolation devices 280 may be, for example, gas gates. Deposition chamber 260 receives streams 250 and 255 containing energized or activated deposition species from separate conduits (not shown) of a microwave applicator (not shown) as described hereinabove. Streams 250 and 255 enter deposition chamber 260 through inlets 220 and 225. Inlets 220 and 225 may correspond to outlets of conduits that pass through a microwave applicator. Streams 250 and 255 are directed to the surface of substrate 230 and combine or other react or interact to form thin film material 275. Deposition chamber may optionally be equipped with independent means for generating a plasma to further energize or activate streams 250 and 255. Additional deposition chambers may be operatively connected to deposition chamber 260 to permit formation of a multilayer thin film structure or device that includes a primer layer and active layer in accordance with the instant invention.

One important multilayer photovoltaic device is the triple junction solar cell, which includes a series of three stacked n-i-p devices with graded bandgaps on a common substrate. The graded bandgap structure provides more efficient collection of the solar spectrum. In making an n-i-p photovoltaic device, a first chamber may be dedicated to the deposition of a layer of an n-type semiconductor material, a second chamber may be dedicated to the deposition of a layer of substantially intrinsic (i-type) semiconductor material, and a third chamber may be dedicated to the deposition of a layer of a p-type semiconductor material. In one embodiment, the intrinsic semiconductor layer is an amorphous semiconductor that includes silicon, germanium, or an alloy of silicon and germanium. The n-type and p-type layers may be microcrystalline or nanocrystalline forms of silicon, germanium, or an alloy of silicon and germanium. The process can be repeated by expanding the deposition apparatus to include additional chambers to achieve additional n-type, p-type, and/or i-type layers in the structure. A triple cell structure, for example, can be achieved by extending the apparatus to include six additional chambers to form a second and third n-i-p structure on the web. Tandem devices and devices that include p-n junctions are also within the scope of the instant invention.

In multilayer devices structures, one or more of the intrinsic, n-type, or p-type layers may be fluorinated and/or hydrogenated forms of silicon prepared in accordance with the principles of the instant invention. One or more primer layers may be included in the device structure prior to the introduction of fluorine to the deposition environment to achieve the benefits of the instant invention.

Those skilled in the art will appreciate that the methods and designs described above have additional applications and that the relevant applications are not limited to the illustrative examples described herein. The present invention may be embodied in other specific forms without departing from the essential characteristics or principles as described herein. The embodiments described above are to be considered in all respects as illustrative only and not restrictive in any manner upon the scope and practice of the invention. It is the following claims, including all equivalents, which define the true scope of the instant invention.

We claim:

1. A device comprising:
a substrate;
a photovoltaic layer disposed over a first area of said substrate, said photovoltaic layer comprising an element capable of reacting with said substrate; and
a primer layer disposed between said substrate and said photovoltaic layer, said primer layer being positioned to preventing reaction of said element with said first area of said substrate.

2. The device of claim 1, wherein said substrate comprises a metal.

3. The device of claim 1, wherein said substrate comprises a plastic.

4. The device of claim 1, wherein said substrate comprises glass.

5. The device of claim 1, wherein photovoltaic layer comprises an amorphous material.

6. The device of claim 1, wherein said photovoltaic layer comprises silicon.

7. The device of claim 6, wherein said element capable of reacting with said substrate is fluorine.

8. The method of claim 7, wherein the atomic concentration of said fluorine is between 0.1% and 7%.

9. The method of claim 7, wherein the atomic concentration of said fluorine is between 0.2% and 5%.

10. The method of claim 7, wherein the atomic concentration of fluorine is between 0.5% and 4%.

11. The device of claim 7, wherein said photovoltaic layer further comprises hydrogen.

12. The device of claim 6, wherein said photovoltaic layer comprises amorphous silicon.

13. The device of claim 12, wherein said primer layer comprises silicon.

14. The device of claim 13, wherein said primer layer comprises amorphous silicon.

15. The device of claim 14, wherein said primer layer further comprises hydrogen.

16. The device of claim 15, wherein said element capable of reacting with said substrate is fluorine.

17. The method of claim 16, wherein the atomic concentration of said fluorine is between 0.1% and 7%.

18. The method of claim 16, wherein the atomic concentration of said fluorine is between 0.2% and 5%.

19. The method of claim 16, wherein the atomic concentration of fluorine is between 0.5% and 4%.

20. The device of claim 16, wherein said photovoltaic layer further comprises hydrogen.

21. The method of claim 20, wherein the atomic concentration of hydrogen is between 1% and 8%.

22. The method of claim 21, wherein the atomic concentration of fluorine is between 0.1% and 7%.

23. The method of claim 20, wherein the atomic concentration of hydrogen is between 2% and 6%.

24. The method of claim 23, wherein the atomic concentration of fluorine is between 0.2% and 5%.

25. The method of claim 20, wherein the atomic concentration of hydrogen is between 3% and 5%.

26. The method of claim 25, wherein the atomic concentration of fluorine is between 0.5% and 4%.

27. The device of claim 16, wherein said primer layer lacks said element capable of reacting with said substrate.

28. The device of claim 16, wherein said photovoltaic layer directly contacts said primer layer.

29. The device of claim 12, wherein said primer layer has a thickness of at least 100 Å.

30. The device of claim 12, wherein said primer layer has a thickness of at least 300 Å.

31. The device of claim 12, wherein said primer layer has a thickness of at least 600 Å.

32. The device of claim 12, wherein said primer layer has a thickness of at least 1200 Å.

33. The device of claim 12, wherein said primer layer has a thickness of at least 1500 Å.

34. The device of claim 12, wherein said primer layer has a thickness of at least 1800 Å.

35. The device of claim 5, wherein said primer layer comprises an amorphous material, said primer layer differing in composition from said photovoltaic layer.

36. The device of claim 35, wherein said photovoltaic layer is fluorinated and said primer layer is non-fluorinated.

37. The device of claim 35, wherein said photovoltaic layer directly contacts said primer layer.

38. The device of claim 1, wherein said primer layer consists essentially of elements other than oxygen.

39. The device of claim 1, wherein primer layer comprises an amorphous material.

40. The device of claim 1, wherein said element capable of reacting with said substrate is further capable of reacting with said primer layer.

41. The device of claim 1, further comprising one or more intervening layers disposed between said primer layer and said substrate.

42. The device of claim 41, wherein said element capable of reacting with said substrate is further capable of reacting with at least one of said one or more layers disposed between said primer layer and said substrate.

43. The device of claim 41, wherein said one or more intervening layers includes an n-type layer or a p-type layer.

44. The device of claim 1, wherein said element capable of reacting with said substrate is capable of etching said substrate.

45. A device comprising:
a first photovoltaic layer, said first photovoltaic layer comprising amorphous silicon; and
a second photovoltaic layer, said second photovoltaic layer comprising amorphous silicon and fluorine.

46. The device of claim 45, wherein said first photovoltaic layer further comprises fluorine.

47. The device of claim 45, wherein said first photovoltaic layer is an intrinsic semiconductor.

48. The device of claim 47, wherein said second photovoltaic layer is an intrinsic semiconductor.

49. The device of claim 45, further comprising a p-type semiconducting layer disposed between said first photovoltaic layer and said second photovoltaic layer.

50. The device of claim 49, further comprising an n-type semiconducting layer disposed between said first photovoltaic layer and said second photovoltaic layer.

51. The device of claim 50, further comprising a substrate, said first photovoltaic layer being disposed between said substrate and said second photovoltaic layer, said device further comprising an n-type or p-type semiconducting layer disposed between said substrate and said first photovoltaic layer.

52. The device of claim 51, further comprising an n-type or p-type semiconducting layer disposed over said second photovoltaic layer.

53. A photovoltaic material comprising amorphous silicon, said amorphous silicon having a peak quantum efficiency at an excitation energy between 1.5 eV and 2.3 eV.

54. The photovoltaic material of claim 53, wherein said amorphous silicon has a peak quantum efficiency at an excitation energy between 1.6 eV and 2.1 eV.

55. The photovoltaic material of claim 53, wherein said amorphous silicon has a peak quantum efficiency at an excitation energy between 1.7 eV and 2.0 eV.
